(19) United States
(12) Patent Application Publication
(10) Pub. No.: US 2025/0373260 A1
(43) Pub. Date: Dec. 4, 2025

(54) DA CONVERSION APPARATUS

(71) Applicant: ADVANTEST CORPORATION, Tokyo (JP)

(72) Inventor: Jun TADA, Gunma (JP)

(21) Appl. No.: 19/183,901

(22) Filed: Apr. 20, 2025

(30) Foreign Application Priority Data
May 30, 2024 (JP) 2024-088318

(51) Int. Cl. H03M 1/66

(52) U.S. Cl. CPC H03M 1/662

(57) ABSTRACT

Provided is a DA conversion apparatus which generates an output signal in analog format obtained by performing DA conversion on a target signal in digital format, the DA conversion apparatus including: a plurality of sub DA conversion units which perform DA conversion on the target signal with a common first sampling period such that relative phases with respect to the target signal are different from each other; a first additional DA conversion unit which performs DA conversion on the target signal with a second sampling period different from the first sampling period; and an output unit which generates the output signal based on respective outputs of the plurality of sub DA conversion units and an output of the first additional DA conversion unit.

The contents of the following patent application(s) are incorporated herein by reference: NO. 2024-088318 filed in JP on May 30, 2024.

### BACKGROUND

### 1. TECHNICAL FIELD

The present invention relates to a DA conversion apparatus.

### 2. RELATED ART

Patent Document 1 describes a digital-to-analog converter.

### Prior Art Documents

### Patent Documents

Patent Document 1: Japanese Patent Application Publication No. 2018-182744

### BRIEF DESCRIPTION OF THE DRAWINGS

FIG. 1 illustrates a first configuration example of a DA conversion apparatus 10 according to the present embodiment.

FIG. 2 illustrates a more detailed configuration of a distribution unit 100 of the DA conversion apparatus 10 according to the present embodiment.

FIG. 3 illustrates an example of a signal timing chart in the DA conversion apparatus 10 according to the present embodiment.

FIG. 4 illustrates a second configuration example of the DA conversion apparatus 10 according to the present embodiment.

FIG. 5 illustrates a more detailed configuration of the distribution unit 100 of the DA conversion apparatus 10 of the second configuration example according to the present embodiment.

FIG. 6 is a diagram illustrating a configuration of a test apparatus 600 together with a device under test 700.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solution of the invention.

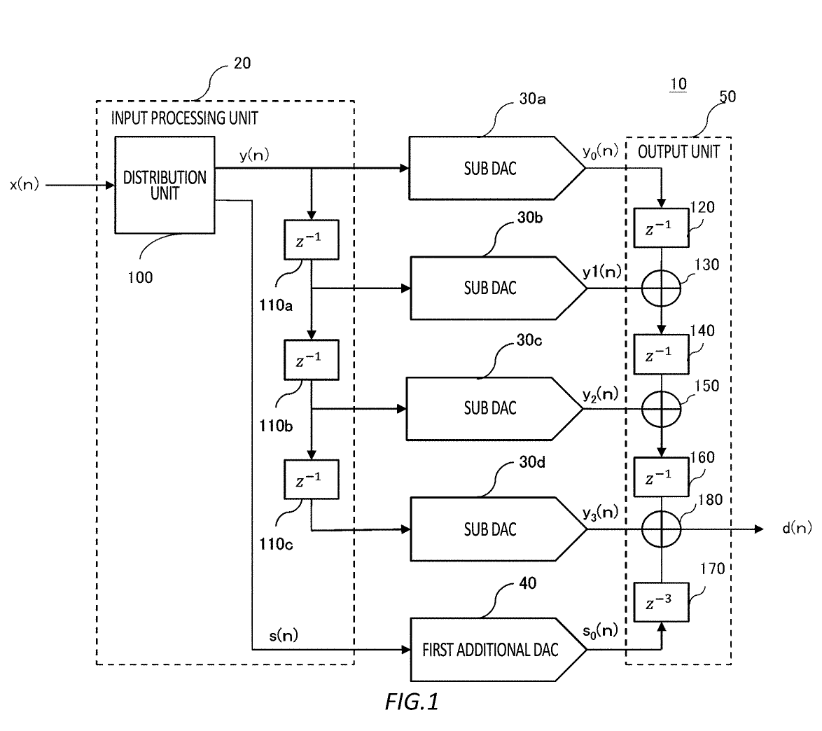

FIG. 1 illustrates a first configuration example of a DA conversion apparatus 10 according to the present embodiment. The DA conversion apparatus 10 generates and outputs an analog output signal obtained by performing DA conversion (digital-analog conversion) on a digital target signal x(n) input to its input terminal. The DA conversion apparatus 10 generates an output signal d(n) by synthesizing a plurality of analog levels generated by performing the DA conversion such that relative phases of the target signal x(n) are different from each other. The DA conversion apparatus 10 may further include a waveform data memory in which the target signal x(n) is stored in advance or an AD converter which outputs the target signal x(n). In addition, the DA conversion apparatus 10 may receive the target signal x(n) from an outside.

The DA conversion apparatus 10 may receive a reference clock and perform the DA conversion according to the reference clock. The target signal x(n) indicating a value (1 bit as an example) may be input to the DA conversion apparatus 10 for each period of the reference clock. The DA conversion apparatus 10 includes an input processing unit 20, a plurality of sub DA conversion units 30, a first additional DA conversion unit 40, and an output unit 50. Here, n indicates a signal corresponding to an n-th value or phase of a bit string of a target signal, and the same applies hereinafter.

The input processing unit 20 outputs a target signal y(n), which is obtained by processing the input target signal x(n), to the sub DA conversion unit 30 and the first additional DA conversion unit 40. The input processing unit 20 may input the target signal y(n) with a different phase to each of the sub DA conversion units 30 and input a target signal s(n) to the first additional DA conversion unit 40. The input processing unit 20 may output a set value (0 as an example) to the sub DA conversion unit 30 at a sampling timing of the first additional DA conversion unit 40. The input processing unit 20 includes a distribution unit 100, a first input delay unit 110a, a second input delay unit 110b, and a third input delay unit 110c. Hereinafter, the first input delay unit 110a, the second input delay unit 110b, and the third input delay unit 110c are also simply referred to as an input delay unit 110 or a plurality of input delay units 110.

The distribution unit 100 may receive the target signal x(n) and input the filtered target signals y(n) and s(n) to the sub DA conversion unit 30 and the first additional DA conversion unit 40, respectively. The distribution unit 100 switches an output destination of the target signal between the sub DA conversion unit 30 and the first additional DA conversion unit 40.

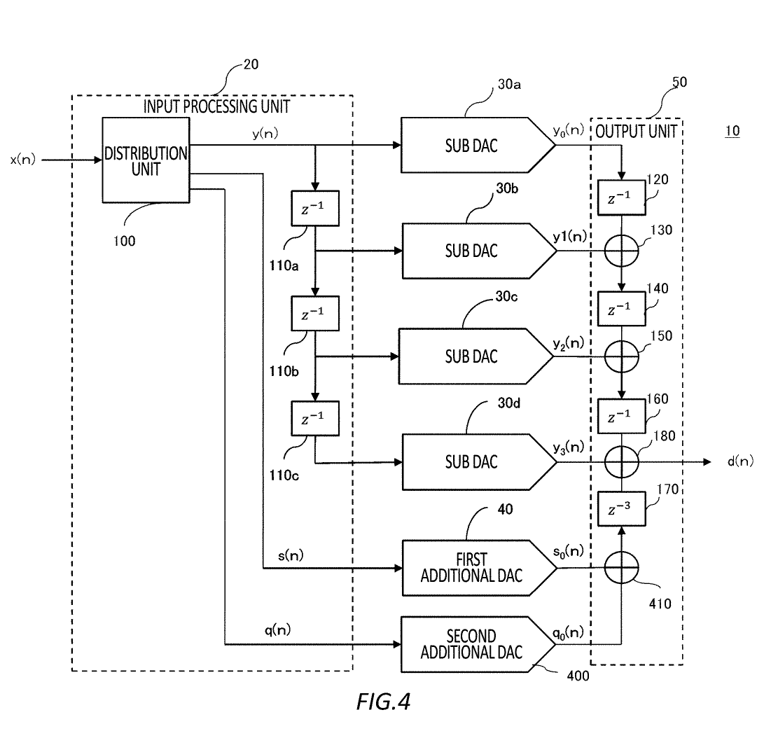

The plurality of input delay units 110 are connected to the distribution unit 100. Each input delay unit 110 may delay the target signal y(n), which is output from the distribution unit 100, by a predetermined delay time. Each of the plurality of input delay units 110 may delay the target signal y(n) by a same delay amount. The predetermined delay time in each input delay unit 110 is, as an example, a time of one period of the reference clock. The plurality of input delay units 110 may be connected to input terminals of the sub DA conversion units 30 which are adjacent thereto, respectively, and connected in series with each other. In the present embodiment of FIG. 1, the first input delay unit 110a is connected between a node between the distribution unit 100 and a first-stage sub DA conversion unit 30a and an input terminal of a second-stage sub DA conversion unit 30b. The second input delay unit 110b is connected between an output terminal of the first input delay unit 110a and an input terminal of a third-stage sub DA conversion unit 30c. The third input delay unit 110c is connected between an output terminal of the second input delay unit 110b and an input terminal of a fourth-stage sub DA conversion unit 30d. As the plurality of input delay units 110, N-1 input delay units 110 may be arranged when N (N = 4 in the present embodiment illustrated in FIG. 4) sub DA conversion units 30 are arranged.

The plurality of sub DA conversion units 30 are connected to the distribution unit 100. The second-stage to fourth-stage sub DA conversion units 30b, 30c, and 30d are connected to the distribution unit 100 via one or more input delay units 110. The plurality of sub DA conversion units 30 perform DA conversion on the target signal y(n) with a common first sampling period such that relative phases with respect to the target signal y(n) are different from each other. Each of the sub DA conversion units 30 may output an analog-level current corresponding to a digital value of the target signal y(n) at a different phase. The target signal y(n), which has relative phases different from each other due to delay by the input delay units 110, may be input to the plurality of sub DA conversion units 30, and the plurality of sub DA conversion units 30 may perform sampling on the input target signal y(n) at a same timing to output analog-level signals (for example, currents) y₀(n) to y₃(n) corresponding to values of the target signal y(n) at different phases, respectively.

In the present embodiment of FIG. 1, the target signal y(n) without delay is input to the first-stage sub DA conversion unit 30a, the target signal y(n) delayed by a predetermined delay time a is input to the second-stage sub DA conversion unit 30b, the target signal y(n) delayed by a delay time 2a is input to the third-stage sub DA conversion unit 30c, and the target signal y(n) delayed by a delay time 3a is input to the fourth-stage sub DA conversion unit 30d. Accordingly, the target signal y(n) delayed by delay times different from each other can be input to the plurality of sub DA conversion units 30, and the plurality of sub DA conversion units 30 can perform the DA conversion such that the relative phases with respect to the target signal y(n) are different from each other.

The first additional DA conversion unit 40 is connected to the distribution unit 100. The first additional DA conversion unit 40 performs DA conversion on the target signal s(n) with a second sampling period different from the first sampling period. The first additional DA conversion unit 40 may output a signal corresponding to a value of the target signal s(n) at the sampling timing of the first additional DA conversion unit 40.

The first sampling period and the second sampling period are integer multiples of the period of the reference clock, and the integer multiples may be coprime to each other. For example, the first sampling period is N times (as an example, N = 4) the period of the reference clock, the second sampling period is M times (as an example, M = 5) the period of the reference clock, and N and M are coprime integers. In addition, M may be N ± 1. As described above, when N and M are coprime integers or a relationship of M = N ± 1 is satisfied, it is possible to reduce overlapping sampling timings between the first sampling periods and the second sampling periods.

The output unit 50 is connected to the plurality of sub DA conversion units 30 and the first additional DA conversion unit 40. The output unit 50 generates the output signal d(n) based on the respective outputs y₀(n) to y₃(n) of the sub DA conversion units 30 and an output s₀(n) of the first additional DA conversion unit 40. The output unit 50 may generate the output signal d(n) by synthesizing the respective outputs y₀(n) to y₃(n) of the sub DA conversion units 30 and the output s₀(n) of the first additional DA conversion unit 40. The output unit 50 may generate the output signal d(n) by adding the respective outputs y₀(n) to y₃(n) of the sub DA conversion units 30 and the output s₀(n) of the first additional DA conversion unit 40. For example, the output unit 50 may generate the output signal d(n) by delaying the respective outputs y₀(n) to y₃(n) of the sub DA conversion units 30 by a third delay time, adding results, and adding, to the added value, a value obtained by delaying the output s₀(n) of the first additional DA conversion unit 40 by a fourth delay time longer than the third delay time. The output unit 50 may generate, as the output signal d(n), the output s₀(n) at the sampling timing of the first additional DA conversion unit 40.

The output unit 50 includes a first output delay unit 120, a first output addition unit 130, a second output delay unit 140, a second output addition unit 150, a third output delay unit 160, a fourth output delay unit 170, and a third output addition unit 180.

The first output delay unit 120 is connected to an output terminal of the first-stage sub DA conversion unit 30a. The first output delay unit 120 may delay the output y₀(n) of the first-stage sub DA conversion unit 30a by the third delay time. The first output addition unit 130 is connected to the first output delay unit 120 and an output terminal of the second-stage sub DA conversion unit 30b. The first output addition unit 130 may add the output y₀(n), which is delayed by the first output delay unit 120, of the first-stage sub DA conversion unit 30a and an output y₁(n) of the second-stage sub DA conversion unit 30b. The second output delay unit 140 is connected to the first output addition unit 130. The second output delay unit 140 delays an output of the first output addition unit 130 by the third delay time. The second output addition unit 150 is connected to the second output delay unit 140 and an output terminal of the third-stage sub DA conversion unit 30. The second output addition unit 150 may add the output, which is delayed by the second output delay unit 140, of the first output addition unit 130 to an output y₂(n) of the third-stage sub DA conversion unit 30c. The third output delay unit 160 is connected to the second output addition unit 150. The third output delay unit 160 may delay an output of the second output addition unit 150 by the third delay time. Note that the third delay time may be a same time as the predetermined delay time in each input delay unit 110.

The fourth output delay unit 170 is connected to an output terminal of the first additional DA conversion unit 40. The fourth output delay unit 170 delays the output s₀(n) of the first additional DA conversion unit 40 by the fourth delay time. The third output addition unit 180 is connected to the third output delay unit 160, the output terminal of the fourth-stage sub DA conversion unit 30d, and the fourth output delay unit 170. The third output addition unit 180 may add the output, which is delayed by the third output delay unit 160, of the second output addition unit 150 to the output y₃(n) of the fourth-stage sub DA conversion unit 30d and the output s₀(n), which is delayed by the fourth output delay unit 170, of the first additional DA conversion unit 40. The fourth delay time may be the same as a sum of the third delay times in the output unit 50. In the present embodiment, the fourth delay time is the same as a total delay time (= third delay time×3) in the first output delay unit 120, the second output delay unit 140, and the third output delay unit 160.

Note that “output of the ... unit” such as “output of the sub DA conversion unit 30” in the description may indicate a signal or a current output by the ... unit, and “input of ... unit” in the description may indicate a signal or a current input to the ... unit. The same applies hereinafter.

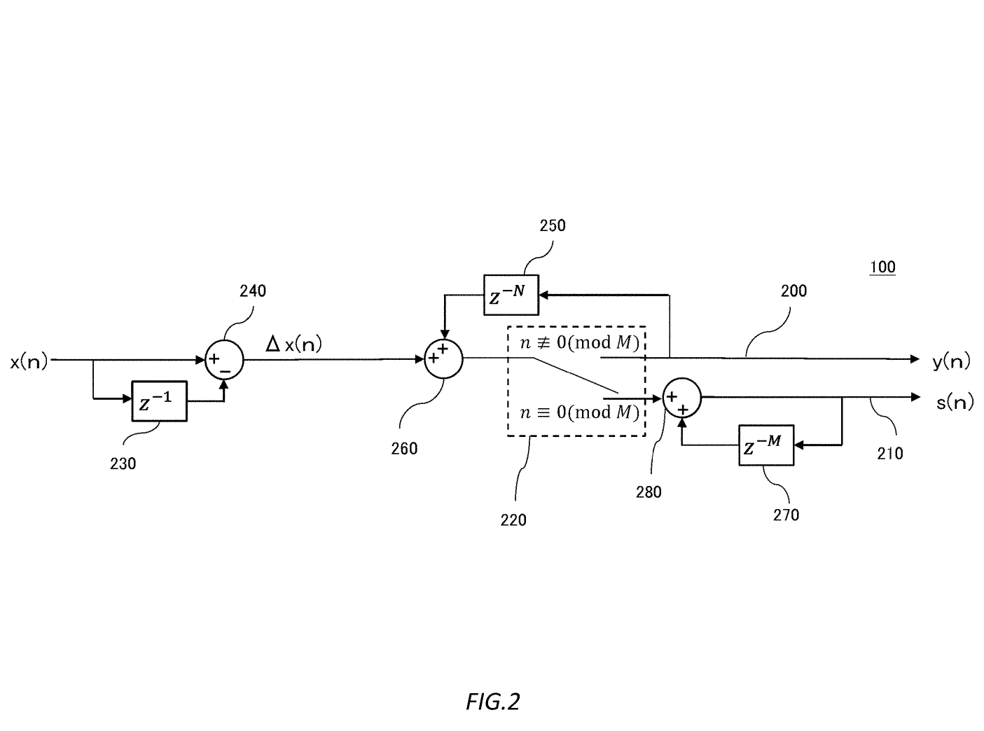

FIG. 2 illustrates a more detailed configuration example of the distribution unit 100 of the DA conversion apparatus 10 according to the present embodiment. The distribution unit 100 includes a first path 200, a second path 210, and a selection unit 220.

The first path 200 is connected between the input terminal of the DA conversion apparatus 10 and the sub DA conversion unit 30. The first path 200 may extract a change amount Δx(n) of the value of the target signal x(n), add the extracted change amount Δx(n) of the value to an input y(n-1) at a previous sampling timing of the sub DA conversion unit 30, and output the added value y(n) to the sub DA conversion unit 30. The first path 200 may include a fourth input delay unit 230, a subtraction unit 240, a fifth input delay unit 250, and a first input addition unit 260.

The fourth input delay unit 230 may be connected to the input terminal of the DA conversion apparatus 10 and delay the input target signal x(n) by a predetermined delay time. The delay time of the fourth input delay unit 230 may be a same time as one period of the reference clock.

The subtraction unit 240 is connected to the input terminal of the DA conversion apparatus 10 and the fourth input delay unit 230. The subtraction unit 240 may extract, as the change amount Δx(n) of the value of the target signal, a difference obtained by subtracting, from the input target signal x(n), a target signal x(n-1) delayed by the fourth input delay unit 230.

The fifth input delay unit 250 is connected to one input terminal of the first input addition unit 260 and the input terminal (that is, an output terminal of the first path 200) of the sub DA conversion unit 30. The fifth input delay unit 250 may delay, by a first delay time, the target signal y(n) output from the first path 200 and input the delayed signal to the first input addition unit 260. Here, as an example, the first delay time is a same time as one period of the first sampling period of the sub DA conversion unit 30 (that is, N times one period of the reference clock). In this case, the fifth input delay unit 250 can input, to the first input addition unit 260, a value output to the sub DA conversion unit 30 at the previous sampling timing of the sub DA conversion unit 30.

The first input addition unit 260 is connected to the subtraction unit 240 and the output terminal of the first path 200. The first input addition unit 260 may add an output y(n-N) of the fifth input delay unit 250 to the target signal x(n) input to the first path 200. In the present embodiment, the first input addition unit 260 may add the output y(n-N) of the fifth input delay unit 250 to the target signal Δx(n) output from the subtraction unit 240. Such a first path 200 may output the output y(n) of the first input addition unit 260 to the sub DA conversion unit 30. Here, the fifth input delay unit 250 is an example of a first delay unit of the present application, and the first input addition unit 260 is an example of a first addition unit of the present application.

The second path 210 is connected between the input terminal of the DA conversion apparatus 10 and the first additional DA conversion unit 40. The second path 210 may extract the change amount Δx(n) of the value of the target signal x(n), add the extracted change amount Δx(n) of the value to an input s(n-M) at a previous sampling timing of the first additional DA conversion unit 40, and output the added value s(n) to the first additional DA conversion unit 40. The second path 210 may share the fourth input delay unit 230, the subtraction unit 240, and the first input addition unit 260 with the first path 200, and may further include a sixth input delay unit 270 and a second input addition unit 280. In the second path 210, the signal y(n) processed in the first path 200 may be processed by the sixth input delay unit 270 and the second input addition unit 280 to be output.

The sixth input delay unit 270 is connected to an output terminal of the second path 210 (an output terminal of the second input addition unit 280 in the present embodiment). The sixth input delay unit 270 may delay, by a second delay time different from the first delay time, the target signal s(n) output from the second path 210 and output the delayed signal to the second input addition unit 280. Here, as an example, the second delay time is a same time as one period of the second sampling period of the first additional DA conversion unit 40 (that is, M times one period of the reference clock). In this case, the sixth input delay unit 270 can input, to the second input addition unit 280, the value s(n-M) (that is, a value previously sampled by the first additional DA conversion unit 40) input to the first additional DA conversion unit 40 at the previous sampling timing of the first additional DA conversion unit 40, at a current sampling timing of the first additional DA conversion unit 40.

The second input addition unit 280 is connected to the first input addition unit 260 via the selection unit 220. The second input addition unit 280 may add the output s(n-M) of the sixth input delay unit 270 to the target signal x(n) input to the second path 210. In the present embodiment, the second input addition unit 280 may add the target signal y(n) output from the first input addition unit 260 to the output s(n-M) of the sixth input delay unit 270 and output the added value s(n) to the first additional DA conversion unit 40. Here, the sixth input delay unit 270 is an example of a second delay unit of the present application, and the second input addition unit 280 is an example of a second addition unit of the present application.

The selection unit 220 is connected to the first input addition unit 260, the second input addition unit 280, and the output terminal of the first path 200. The selection unit 220 is, as an example, a switch or a multiplexer. The selection unit 220 may select one of the first path 200 and the second path 210 based on the sampling timing of the first additional DA conversion unit 40. For example, among the first path 200 and the second path 210, the selection unit 220 may select the first path 200 at a timing different from the sampling timing of the first additional DA conversion unit 40, and select the second path 210 at the sampling timing of the first additional DA conversion unit 40. The selection unit 220 may select one of the first path 200 and the second path 210, and output the processed target signal from the selected path to one of the sub DA conversion unit 30 and the first additional DA conversion unit 40. In response to the selection unit 220 selecting the first path 200, the distribution unit 100 may be connected from the input terminal of the DA conversion apparatus 10 to the sub DA conversion unit 30, so as to output the target signal y(n) to the sub DA conversion unit 30. In response to the selection unit 220 selecting the second path 210, the distribution unit 100 may be connected from the input terminal of the DA conversion apparatus 10 to the first additional DA conversion unit 40, so as to output the target signal s(n) to the first additional DA conversion unit 40.

When the second path 210 is selected by the selection unit 220, the first path 200 may output the set value (0 as an example) to the sub DA conversion unit 30. Accordingly, at the sampling timing of the first additional DA conversion unit 40, the input processing unit 20 can output the set value to the sub DA conversion unit 30 via the first path 200, and on the other hand, can output the target signal s(n) to the first additional DA conversion unit 40 via the second path 210. In addition, at a timing other than the sampling timing of the first additional DA conversion unit 40, the input processing unit 20 may output the target signal y(n) to the sub DA conversion unit 30 via the first path 200, and on the other hand, may output the set value to the first additional DA conversion unit 40 via the second path 210.

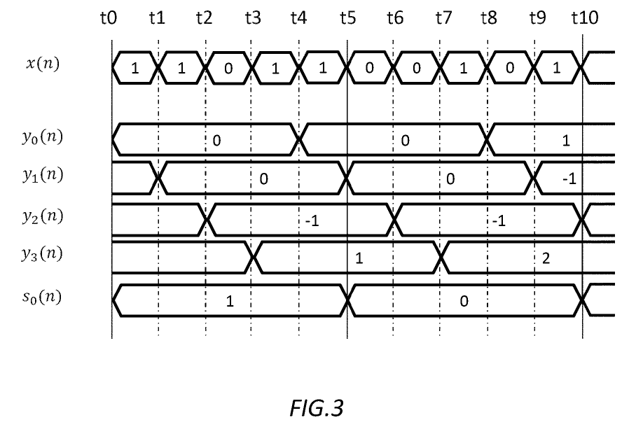

FIG. 3 illustrates an example of a signal timing chart in the DA conversion apparatus 10 according to the present embodiment. FIG. 3 illustrates an example of N = 4 and M = 5. Each of t0 to t10 indicates a change timing of the reference clock, and each of t0 to t1, t1 to t2, ..., t8 to t9, and t9 to t10 indicates the period of the reference clock. x(n) represents the bit string of the target signal input to the input terminal of the DA conversion apparatus 10. y₀(n) represents the output of the sub DA conversion unit 30a in a first column. y₁(n) represents the output of the sub DA conversion unit 30b in a second column. y₂(n) represents the output of the sub DA conversion unit 30c in a third column. y₃(n) represents the output of the sub DA conversion unit 30d in a fourth column. s₀(n) represents the output of the first additional DA conversion unit 40. In FIG. 3, the outputs of sub DA conversion units 30 and first additional DA conversion unit 40 are indicated by bit values corresponding to the outputs.

Regarding the target signal at t0, since t0 is the sampling timing, the first additional DA conversion unit 40 samples value '1' of the input target signal and outputs a current corresponding to value '1'. Since the target signal at t0 is the sampling target, but t0 is the sampling timing of the first additional DA conversion unit 40, the sub DA conversion unit 30a in the first column outputs a current corresponding to set value '0'. Accordingly, for the target signal having value '1' in t0 to t1, the output unit 50 can generate an output signal corresponding to total value '1' of the outputs of the sub DA conversion units 30 and the first additional DA conversion unit 40.

For the target signal at t1, since t1 is not the sampling timing, the first additional DA conversion unit 40 continues outputting the current corresponding to value '1'. Since the target signal at t1 is not the sampling target, the sub DA conversion unit 30a in the first column continues outputting the current corresponding to set value '0'. Since the target signal at t1 is the sampling target, the sub DA conversion unit 30b of the second column samples value '0' of the input signal and outputs a current corresponding to value '0'. Accordingly, for the target signal having value '1' in t1 to t2, the output unit 50 can generate the output signal corresponding to total value '1' of the outputs of the sub DA conversion units 30 and the first additional DA conversion unit 40.

For the target signal at t2, since t2 is not the sampling timing, the first additional DA conversion unit 40 continues outputting the current corresponding to value '1'. Since the target signal at t2 is not the sampling target, the sub DA conversion unit 30a in the first column and the sub DA conversion unit 30b in the second column continue outputting a same current. Since the target signal at t2 is the sampling target, the sub DA conversion unit 30c of the third column samples a value “-1” of the input signal and outputs a current corresponding to the value “-1”. Accordingly, for the target signal having value '0' in t2 to t3, the output unit 50 can generate an output signal corresponding to total value '0' of the outputs of the sub DA conversion units 30 and the first additional DA conversion unit 40.

For the target signal at t3, since t3 is not the sampling timing, the first additional DA conversion unit 40 continues outputting the current corresponding to value '1'. Since the target signal at t3 is not the sampling target, the sub DA conversion unit 30a in the first column, the sub DA conversion unit 30b in the second column, and the sub DA conversion unit 30c in the third column continue outputting same currents. Since the target signal at t3 is the sampling target, the sub DA conversion unit 30d in the fourth column samples value '1' of the input signal and outputs the current corresponding to value '1'. Accordingly, for the target signal having value '1' in t3 to t4, the output unit 50 can generate the output signal corresponding to total value '1' of the outputs of the sub DA conversion units 30 and the first additional DA conversion unit 40.

For the target signal at t4, since t4 is not the sampling timing, the first additional DA conversion unit 40 continues outputting the current corresponding to value '1'. Since the target signal at t4 is the sampling target, the sub DA conversion unit 30a in the first column samples value '0' of the input signal and outputs the current corresponding to value '0'. Since the target signal at t4 is not the sampling target, the sub DA conversion unit 30b in the second column, the sub DA conversion unit 30c in the third column, and the sub DA conversion unit 30d in the fourth column continue outputting same currents. Accordingly, for the target signal having value '1' in t4 to t5, the output unit 50 can generate the output signal corresponding to total value '1' of the outputs of the sub DA conversion units 30 and the first additional DA conversion unit 40.

Regarding the target signal at t5, since t5 is the sampling timing, the first additional DA conversion unit 40 samples value '0' of the input signal and outputs the current corresponding to value '0'. Since the target signal at t5 is the sampling target, but t5 is the sampling timing of the first additional DA conversion unit 40, the sub DA conversion unit 30b in the second column outputs the current corresponding to set value '0'. Since the target signal at t5 is not the sampling target, the sub DA conversion unit 30a in the first column, the sub DA conversion unit 30c in the third column, and the sub DA conversion unit 30d in the fourth column continue outputting same currents. Accordingly, for the target signal having value '0' in t5 to t6, the output unit 50 can generate the output signal corresponding to total value '0' of the outputs of the sub DA conversion units 30 and the first additional DA conversion unit 40.

The DA conversion apparatus 10 of the present embodiment can generate an output signal after t6 similarly to those at t1 to t6. A calculation procedure in the distribution unit 100 of the DA conversion apparatus 10 of the present embodiment will be described below.

### Expression 1

In the calculation procedure of the DA conversion apparatus 10 expressed in Expression 1, x(n) represents a value of the target signal at an n-th phase (tn in FIG. 3), yᵢ(n) represents an output of the sub DA conversion unit 30 in an (i+1)-th column to which the target signal at the n-th phase is input, and s₀(n) represents an output of the first additional DA conversion unit 40 to which the target signal at the n-th phase is input. N represents a multiple of the sampling period of the sub DA conversion unit 30 with respect to the period of the reference clock, and M represents a multiple of the sampling period of the first additional DA conversion unit 40 with respect to the period of the reference clock.

The output of the first additional DA conversion unit 40 having a different sampling rate is used instead of a part of the outputs of the sub DA conversion units 30 by the DA conversion apparatus 10 of the present embodiment, whereby it is possible to suppress divergence of the output signal of the DA conversion apparatus 10. In addition, by a mounting method in which the sub DA conversion unit 30 and the first additional DA conversion unit 40 having sampling rates lower than an overall sampling rate of the DA conversion apparatus 10 are combined and the output unit 50 uses a simple addition method, precise waveform reproduction in an entire band up to a Nyquist frequency can be performed in a finite dynamic range.

FIG. 4 illustrates a second configuration example of the DA conversion apparatus 10 according to the present embodiment. The DA conversion apparatus 10 of the second configuration example may have a configuration similar to that of the DA conversion apparatus 10 of the first configuration example illustrated in FIG. 1 and execute a similar operation, but further includes a second additional DA conversion unit 400. Hereinafter, a configuration different from the first configuration example of FIG. 1 will be mainly described.

The second additional DA conversion unit 400 is connected to the distribution unit 100. The second additional DA conversion unit 400 may perform DA conversion on a target signal q(n), which is output from the distribution unit 100, with a third sampling period different from both the first sampling period and the second sampling period. The third sampling period may be an integer multiple L of the period of the reference clock, and the multiple L may be a multiple that is coprime to the multiples N and M of the first sampling period and the second sampling period or a consecutive value of the multiples N and M. For example, when N = 4 and M = 5, the third sampling period may be six times or seven times the period of the reference clock.

The output unit 50 may generate an output signal based on the respective outputs yᵢ(n) of the sub DA conversion units 30, the output s₀(n) of the first additional DA conversion unit 40, and the output q₀(n) of the second additional DA conversion unit 400. The output unit 50 may generate the output signal by synthesizing the respective outputs yᵢ(n) of the sub DA conversion units 30, the output s₀(n) of the first additional DA conversion unit 40, and the output q₀(n) of the second additional DA conversion unit 400. The output unit 50 may further include a fourth output addition unit 410.

The fourth output addition unit 410 is connected to the first additional DA conversion unit 40, the second additional DA conversion unit 400, and the fourth output delay unit 170. The fourth output addition unit 410 may add the output s₀(n) of the first additional DA conversion unit 40 to the output q₀(n) of the second additional DA conversion unit 400. The fourth output delay unit 170 may delay an output of the fourth output addition unit 410 by the fourth delay time and output the delayed output to the third output addition unit 180. The third output addition unit 180 may add the output, which is delayed by the third output delay unit 160, of the second output addition unit 150 to the output y₃(n) of the fourth-stage sub DA conversion unit 30d and the output, which is delayed by the fourth output delay unit 170, of the fourth output addition unit 410. Accordingly, the third output addition unit 180 may output the added signal as the output signal d(n).

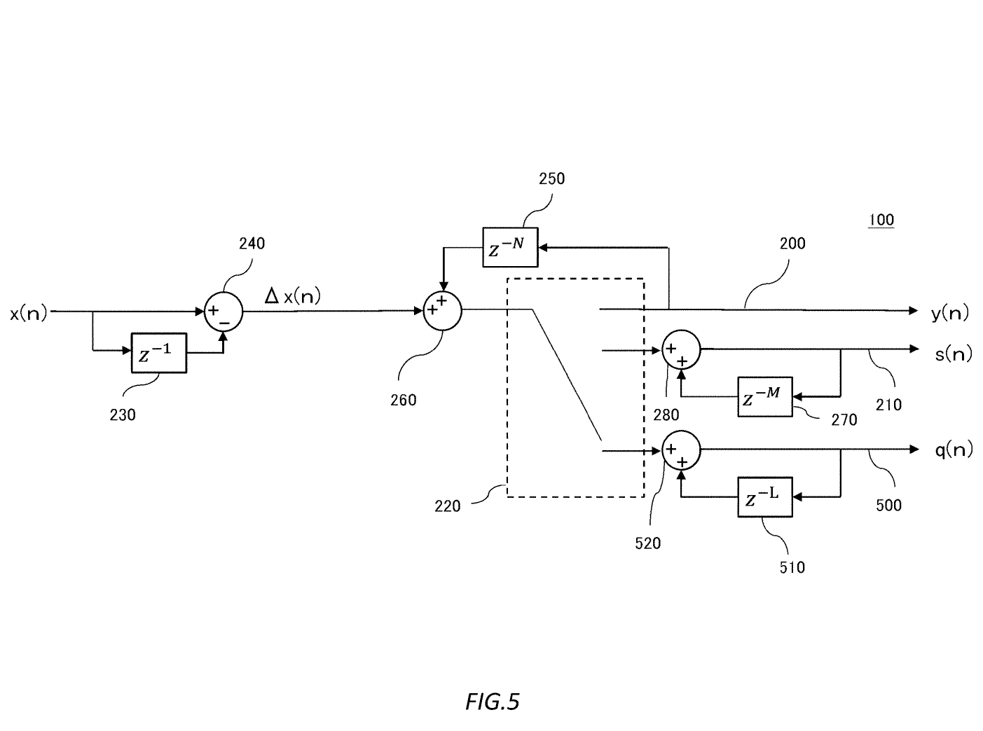

FIG. 5 illustrates a configuration of the distribution unit 100 of the DA conversion apparatus 10 of the second configuration example according to the present embodiment. The distribution unit 100 of the second configuration example may have a configuration similar to that of the distribution unit 100 illustrated in FIG. 2 and execute a similar operation, but further includes a third path 500. Hereinafter, a configuration different from the configuration example of FIG. 2 will be mainly described.

The third path 500 is connected between the input terminal of the DA conversion apparatus 10 and the second additional DA conversion unit 400. The third path 500 may extract the change amount Δx(n) of the value of the target signal x(n), add the extracted change amount Δx(n) of the value to an input q(n-L) at a previous sampling timing of the second additional DA conversion unit 400, and input a result to the second additional DA conversion unit 400. The third path 500 may shares the fourth input delay unit 230, the subtraction unit 240, and the first input addition unit 260 with the first path 200 and the second path 210, and may further include a seventh input delay unit 510 and a third input addition unit 520. In the third path 500, the signal processed in the first path 200 may be processed by the seventh input delay unit 510 and the third input addition unit 520, and the processed signal q(n) may be output to the second additional DA conversion unit 400.

The seventh input delay unit 510 is connected to an output terminal of the third path 500 (an output terminal of the third input addition unit 520 in the present embodiment) and one input terminal of the third input addition unit 520. The seventh input delay unit 510 may delay the target signal, which is output from the third path 500, by a delay time different from both the first delay time and the second delay time, and input the delayed signal q(n-L) to the third input addition unit 520. Here, as an example, the delay time of the seventh input delay unit 510 is a same time as one period of the third sampling period of the second additional DA conversion unit 400 (that is, L times one period of the reference clock). In this case, the seventh input delay unit 510 can input, to the third input addition unit 520, the value (that is, a value previously sampled by the first additional DA conversion unit 40) output to the second additional DA conversion unit 400 at the previous sampling timing of the second additional DA conversion unit 400, at a current sampling timing of the second additional DA conversion unit 400.

The third input addition unit 520 is connected to the first input addition unit 260 via the selection unit 220. The third input addition unit 520 may add the output q(n-L) of the seventh input delay unit 510 to the target signal input to the third path 500. In the present embodiment, the third input addition unit 520 may add the target signal y(n) output from the first input addition unit 260 to the output q(n-L) of the seventh input delay unit 510 and output the signal q(n) to the second additional DA conversion unit 400.

The selection unit 220 is connected to the first input addition unit 260, the second input addition unit 280, the third input addition unit 520, and the output terminal of the first path 200. The selection unit 220 may select any one of the first path 200, the second path 210, and the third path 500 based on the sampling timing of the first additional DA conversion unit 40 and the sampling timing of the second additional DA conversion unit 400. For example, among the first path 200, the second path 210, and the third path 500, the selection unit 220 may select the first path 200 at a timing different from the sampling timing of the first additional DA conversion unit 40 and the sampling timing of the second additional DA conversion unit 400, select the second path 210 at the sampling timing of the first additional DA conversion unit 40, and select the third path 500 at the sampling timing of the second additional DA conversion unit 400. In response to the selection unit 220 selecting the third path 500, the distribution unit 100 may be connected from the input terminal of the DA conversion apparatus 10 to the second additional DA conversion unit 400, so as to output the target signal q(n) to the second additional DA conversion unit 400. A path that is not selected by the selection unit 220 may output the set value (0 as an example).

Note that the second configuration example of the DA conversion apparatus 10 of the present embodiment may further include an additional DA conversion unit having a sampling period different from that of any of the sub DA conversion unit 30, the first additional DA conversion unit 40, and the second additional conversion unit.

Note that the DA conversion apparatus 10 of the first configuration example or the second configuration example of the present embodiment samples the target signal s(n) in the first additional DA conversion unit 40 at each sampling timing of the first additional DA conversion unit 40 and generates the output signal in the output unit 50, but is not limited thereto, and the target signal s(n) may be sampled in the first additional DA conversion unit 40 at a part of the sampling timing of the first additional DA conversion unit 40.

For example, the selection unit 220 may select the second path 210 among the first path 200 and the second path 210 at an intermittent timing among the sampling timings of the first additional DA conversion unit 40. The selection unit 220 may select the second path 210 at one sampling timing in a plurality of timings in the first additional DA conversion unit 40, and select the first path 200 at a timing, at which the second path 210 is not selected, among the sampling timings of the first additional DA conversion unit 40. For example, the selection unit 220 may alternately select the first path 200 and the second path 210 at the sampling timings of the first additional DA conversion unit 40.

For example, the selection unit 220 may select the second path 210 such that the outputs (that is, the outputs of the first input addition unit 260 and the second input addition unit 280) to the sub DA conversion unit 30 and the first additional DA conversion unit 40 become smaller values at the sampling timing of the first additional DA conversion unit 40. The selection unit 220 may decide a timing to select the second path 210 among the sampling timings of the first additional DA conversion unit 40 for each bit pattern of the input target signal x(n). For each bit pattern of the target signal x(n), the selection unit 220 may decide in advance a combination that minimizes the values to be output to the sub DA conversion unit 30 and the first additional DA conversion unit 40, among all combinations of the first path 200 and the second path 210 selected for each sampling timing of the first additional DA conversion unit 40, by decision tree analysis or the like. As an example, for the bit pattern of the target signal x(n) input at a plurality (five as an example) of sampling timings (as an example, t0, t5, t10, t15, t20 in FIG. 3) of the first additional DA conversion unit 40, the selection unit 220 may decide in advance a combination of paths to be selected so as to minimize the outputs to the sub DA conversion unit 30 and the first additional DA conversion unit 40. As an example, the selection unit 220 may decide in advance a combination of selecting the first path 200 at t0, selecting the first path 200 at t5, selecting the second path 210 at t10, selecting the second path 210 at t15, and selecting the first path 200 at t20. Accordingly, ranges of the sub DA conversion unit 30 and the first additional DA conversion unit 40 can be further reduced, and a cost of the DA conversion apparatus 10 can be reduced.

In addition, similarly to the second path 210, the selection unit 220 in the DA conversion apparatus 10 of the second configuration example may select the third path 500 among the first path 200, the second path 210, and the third path 500 at an intermittent timing among the sampling timings of the second additional DA conversion unit 400. The selection unit 220 may select the first path 200 at a timing, at which the third path 500 is not selected, among the sampling timings of the second additional DA conversion unit 400. The selection unit 220 may select the third path 500 such that the outputs to the sub DA conversion unit 30, the first additional DA conversion unit 40, and the second additional DA conversion unit 400 become smaller (minimized), at an intermittent timing among the sampling timings of the second additional DA conversion unit 400. Similarly to the second path 210, the selection unit 220 may decide a timing to select the third path 500 among the sampling timings of the second additional DA conversion unit 400 for each bit pattern of the input target signal x(n).

In addition, similarly, the selection unit 220 may decide a combination of the timing to select the second path 210 among the sampling timings of the first additional DA conversion unit 40 and the timing to select the third path 500 among the sampling timings of the second additional DA conversion unit 400, such that the outputs to the sub DA conversion unit 30, the first additional DA conversion unit 40, and the second additional DA conversion unit 400 become smaller (minimized).

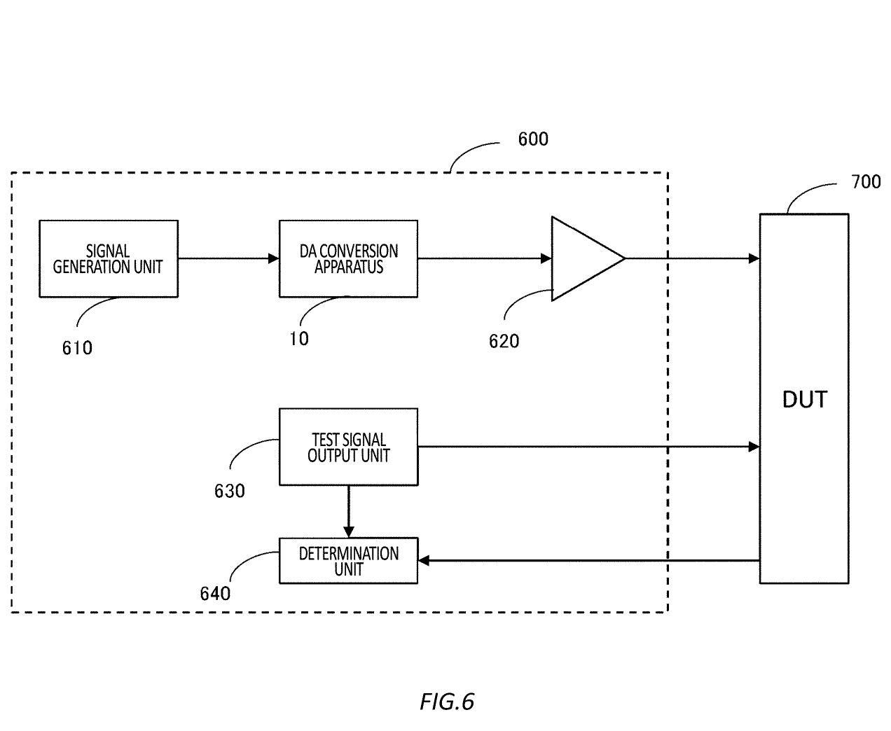

FIG. 6 is a diagram illustrating a configuration of a test apparatus 600 together with a device under test 700. The test apparatus 600 tests the device under test 700, such as an analog circuit, a digital circuit, a memory, and a system-on-chip (SOC).

The test apparatus 600 includes a signal generation unit 610, the DA conversion apparatus 10, a voltage supply unit 620, a test signal output unit 630, and a determination unit 640. The DA conversion apparatus 10 generates a voltage to be applied to the device under test 700. Since the DA conversion apparatus 10 has a configuration similar to that of the DA conversion apparatus 10 according to the present embodiment described with reference to FIGS. 1 to 5, the description thereof will be omitted.

The signal generation unit 610 outputs, as a digital value, the voltage to be supplied to the device under test 700, to the DA conversion apparatus 10. The DA conversion apparatus 10 outputs an analog output signal corresponding to a digital target signal. The voltage supply unit 620 supplies, to the device under test 700, a test voltage corresponding to the output signal generated by the DA conversion apparatus 10. The voltage supply unit 620 is, for example, a power amplifier.

The test signal output unit 630 outputs a test signal to the device under test 700. The DA conversion apparatus 10 may be used as a part of the test signal output unit 630. In addition, the test signal output unit 630 may output, to the determination unit 640, an expected value output by the device under test 700 according to the test signal. The determination unit 640 receives, from the device under test 700, a response signal corresponding to the test signal. Then, the determination unit 640 determines a quality of the device under test 700 based on the received response signal.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, steps, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as "first" or "next" for the sake of convenience in the claims, specification, or drawings, it does not necessarily mean that the process must be performed in this order.

What is claimed is:

1. A DA conversion apparatus which generates an output signal in analog format obtained by performing DA conversion on a target signal in digital format, the DA conversion apparatus comprising:
a plurality of sub DA conversion units which perform DA conversion on the target signal with a common first sampling period such that relative phases with respect to the target signal are different from each other;
a first additional DA conversion unit which performs DA conversion on the target signal with a second sampling period different from the first sampling period; and
an output unit which generates the output signal based on respective outputs of the plurality of sub DA conversion units and an output of the first additional DA conversion unit.

2. The DA conversion apparatus according to claim 1, wherein
the first sampling period and the second sampling period are integer multiples of a period of a reference clock, and the integer multiples are coprime to each other.

3. The DA conversion apparatus according to claim 1, wherein
the output unit generates the output signal by adding the respective outputs of the plurality of sub DA conversion units and the output of the first additional DA conversion unit.

4. The DA conversion apparatus according to claim 1, further comprising
an input processing unit which outputs the target signal with a different phase to each of the plurality of sub DA conversion units and outputs the target signal to the first additional DA conversion unit.

5. The DA conversion apparatus according to claim 4, wherein
the input processing unit outputs a set value to the sub DA conversion unit at a sampling timing of the first additional DA conversion unit.

6. The DA conversion apparatus according to claim 5, wherein
the input processing unit outputs 0, which is the set value, to the sub DA conversion unit at the sampling timing of the first additional DA conversion unit.

7. The DA conversion apparatus according to claim 4, wherein
the first additional DA conversion unit outputs a signal corresponding to a value of the target signal at a sampling timing of the first additional DA conversion unit.

8. The DA conversion apparatus according to claim 4, wherein
the output unit generates, as the output signal, an output at a sampling timing of the first additional DA conversion unit.

9. The DA conversion apparatus according to claim 4, wherein
the input processing unit includes
a first path which extracts a change amount of a value of the target signal, adds the change amount, having been extracted, of the value to an input at a previous sampling timing of each of the sub DA conversion units, and outputs a result to the sub DA conversion unit,
a second path which extracts a change amount of the value of the target signal, adds the change amount, having been extracted, of the value to an input at a previous sampling timing of the first additional DA conversion unit, and outputs a result to the first additional DA conversion unit, and
a selection unit which selects one of the first path and the second path based on a sampling timing of the first additional DA conversion unit.

10. The DA conversion apparatus according to claim 9, wherein
the first path outputs 0 when the second path is selected by the selection unit.

11. The DA conversion apparatus according to claim 9, wherein
among the first path and the second path, the selection unit selects the first path at a timing different from the sampling timing of the first additional DA conversion unit, and selects the second path at the sampling timing of the first additional DA conversion unit.

12. The DA conversion apparatus according to claim 11, wherein
the selection unit selects the second path among the first path and the second path at an intermittent timing of sampling timings of the first additional DA conversion unit.

13. The DA conversion apparatus according to claim 9, wherein
the first path includes
a first delay unit which delays, by a first delay time, the target signal output from the first path, and
a first addition unit which adds an output of the first delay unit to the target signal input to the first path, and
the second path includes
a second delay unit which delays, by a second delay time different from the first delay time, the target signal output from the second path, and
a second addition unit which adds an output of the second delay unit to the target signal input to the second path.

14. The DA conversion apparatus according to claim 1, wherein
the output unit generates the output signal by delaying the respective outputs of the sub DA conversion units by a third delay time, adding results, and adding, to a value obtained the adding, a value obtained by delaying the output of the first additional DA conversion unit by a fourth delay time longer than the third delay time.

15. The DA conversion apparatus according to claim 14, wherein
the fourth delay time is identical to a sum of third delay times including the third delay time in the output unit.

16. The DA conversion apparatus according to claim 1, further comprising
a second additional DA conversion unit which performs DA conversion on the target signal with a third sampling period different from both the first sampling period and the second sampling period, wherein
the output unit generates the output signal based on the respective outputs of the plurality of sub DA conversion units, the output of the first additional DA conversion unit, and an output of the second additional DA conversion unit.
